(19) United States
(12) Patent Application Publication
(10) Pub. No.: US 2024/0381634 A1
(43) Pub. Date: Nov. 14, 2024

(54) SEMICONDUCTOR DEVICE MANUFACTURING METHOD

(71) Applicant: SK keyfoundry Inc., Cheongju-si (KR)

(72) Inventors: Yangbeom KANG, Cheongju-si (KR); Seungmo JO, Cheongju-si (KR); Gyeoungmin MIN, Jeju-si (KR)

(73) Assignee: SK keyfoundry Inc., Cheongju-si (KR)

(21) Appl. No.: 18/470,923

(22) Filed: Sep. 20, 2023

(30) Foreign Application Priority Data
May 11, 2023 (KR) 10-2023-0060856

(51) Int. Cl. H10B 41/30; H10B 41/42

(52) U.S. Cl. CPC H10B 41/30; H10B 41/42

(57) ABSTRACT

A semiconductor device manufacturing method includes forming a tunneling gate insulating layer and a floating gate Poly-Si layer in a substrate, an inter-poly dielectric layer on the floating gate Poly-Si layer, a control gate Poly-Si layer on the inter-poly dielectric layer, and a control gate hard mask layer on the control gate Poly-Si layer, performing a patterning process on the control gate hard mask layer, the control gate Poly-Si layer, the inter-poly dielectric layer, the floating gate Poly-Si layer and the tunneling gate insulating layer to form a gate stack, forming a select gate insulating layer on the gate stack, and a select gate disposed on the select gate insulating layer, performing a removing process on the select gate insulating layer and the control gate hard mask to expose a top surface of the control gate, and forming a silicide layer on the control gate.

### CROSS-REFERENCE TO RELATED APPLICATION(S)

This application claims the benefit under 35 USC § 119 (a) of Korean Patent Application No. 10-2023-0060856 filed on May 11, 2023, in the Korean Intellectual Property Office, the entire disclosure of which is incorporated herein for all purposes.

### BACKGROUND

### 1. Field

The following description relates to a semiconductor device manufacturing method, in particular a method for removing a hard mask used to form a pattern of a stacked gate in a method for manufacturing a non-volatile memory device as well as a logic device.

### 2. Description of Related Art

A typical semiconductor device is largely divided into a memory device and a non-memory device. The memory device is divided into a volatile memory device such as DRAM and SRAM and a non-volatile memory device such as a flash memory and an electrically erasable programmable read-only memory (EEPROM). The non-volatile memory device may have a structure in which a floating gate that is an area where electrons are stored due to the characteristics of electric electrons, particularly of electrons that must be stored and a control gate that controls the storage and release of electrons of the floating gate that are stacked. Here, a hard mask oxide layer is used to form a pattern of the stacked gate. If the oxide layer remains on the top of the stacked gate, the source/drain ion implantation and silicide formation are disturbed in the subsequent process, and cell characteristics are affected. In addition, for this reason, if the oxide layer is removed by wet etching, the tunneling oxide layer below the floating gate and the dielectric layer structure between the floating gate and the control gate are damaged, resulting in the deterioration of the cell characteristics.

### SUMMARY

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

In one general aspect, a semiconductor device manufacturing method includes: preparing a first region and a second region on a substrate; forming a tunneling gate insulating layer and a floating gate Poly-Si layer in a first region and a second region of a substrate; forming an inter-poly dielectric layer on the floating gate Poly-Si layer; forming a control gate Poly-Si layer on the inter-poly dielectric layer; forming a control gate hard mask layer on the control gate Poly-Si layer; performing a patterning process on the control gate hard mask layer, the control gate Poly-Si layer, the inter-poly dielectric layer, the floating gate Poly-Si layer and the tunneling gate insulating layer to form a gate stack including a control gate hard mask, a control gate, an inter-poly dielectric pattern, a floating gate and a tunneling gate insulating pattern; forming a select gate insulating layer on the gate stack; forming a select gate disposed on the select gate insulating layer, wherein the select gate is disposed on one sidewall of the gate stack as a spacer shape; performing a removing process on the select gate insulating layer and the control gate hard mask to expose a top surface of the control gate; and forming a silicide layer on the control gate.

The performing of a removing process on the select gate insulating layer and the control gate hard mask to expose the top surface of the control gate may include: coating an organic bottom anti-reflective coating (BARC) layer on the gate stack; partially removing the BARC layer disposed on the gate stack, resulting in exposing the select gate insulating layer; removing the select gate insulating layer and the control gate hard mask disposed on the control gate; and removing the remaining BARC layer.

The partially removing of the BARC layer disposed on the gate stack may include a dry etch-back process.

The removing of the select gate insulating layer and the control gate hard mask disposed on the control gate may include at least one of a dry etching process, a wet etching process or a combination thereof.

The removing of the remaining BARC layer may include a plasma ashing process.

The dry etch-back process may include a descum process, wherein a process condition in the descum process may include an oxygen flow rate and a plasma power lower than those of the plasma ashing process.

The BARC may include: a first portion covered on the gate stack; and a second portion covered on the select gate, the second portion having a thickness greater than a thickness of the first portion.

The semiconductor device manufacturing method may further include: forming a logic gate insulating layer in the second region of the substrate; forming a logic gate Poly-Si layer on the logic gate insulating layer; and forming a logic gate hard mask layer on the logic gate Poly-Si layer, wherein the logic gate hard mask layer is simultaneously formed with the control gate hard mask layer.

The removing of the BARC layer may be implemented while preventing damage to the tunneling gate insulating layer below the floating gate Poly-Si layer and the inter-poly dielectric pattern between the floating gate Poly-Si layer and the control gate.

In another general aspect, a semiconductor device manufacturing method may include: preparing a first region and a second region on a substrate; forming a gate stack in the first region, the gate stack comprising a control gate hard mask, a control gate, an inter-poly dielectric pattern, a floating gate, and a tunneling gate dielectric pattern; forming a stacked structure in the second region, the stacked structure comprising a logic gate insulating layer, a logic gate Poly-Si layer, and a logic gate hard mask layer; forming a select gate disposed on one sidewall of the gate stack as a spacer shape in the first region; removing the logic gate hard mask layer disposed on the logic gate Poly-Si layer, and patterning the stacked structure to form a logic gate in the second region; removing the control gate hard mask to expose the control gate; and forming a silicide layer on the control gate in the first region.

The removing of the control gate hard mask to expose the control gate may include: forming a coating layer to cover the gate stack and the stacked structure; partially etching the coating layer to expose the control gate hard mask layer; removing the control gate hard mask layer; and removing the coating layer disposed on the gate stack and the stacked structure.

The coating layer may include a bottom anti-reflective coating (BARC) layer.

The forming of a gate stack in the first region may include: forming a tunneling gate insulating layer and a floating gate Poly-Si layer in the first region; forming an inter-poly dielectric layer on the floating gate Poly-Si layer; forming a control gate Poly-Si layer on the inter-poly dielectric layer; forming a control gate hard mask layer on the control gate Poly-Si layer; and performing a patterning process on the control gate hard mask layer, the control gate Poly-Si layer, the inter-poly dielectric layer, the floating gate Poly-Si layer and the tunneling gate insulating layer to form a control gate hard mask, a control gate, an inter-poly dielectric pattern, a floating gate and a tunneling gate insulating pattern.

The partially etching of the coating layer disposed on the control gate hard mask layer may include a descum process using oxygen plasma.

The removing of the control gate hard mask layer may include at least one of a dry etching process, a wet etching process or a combination thereof.

The removing of the coating layer disposed on the gate stack and the stacked structure may include an ashing process using oxygen plasma, and the descum process may operate at oxygen flow rates lower than the plasma ashing process.

Other features and aspects will be apparent from the following detailed description, the drawings, and the claims.

### BRIEF DESCRIPTION OF THE DRAWINGS

FIGS. 1, 2, 3 and 4 illustrate an example of forming a gate stack and a stacked structure according to an embodiment of the present disclosure.

FIGS. 5, 6 and 7 illustrate an example of forming a select gate according to an embodiment of the present disclosure.

FIGS. 8 and 9 illustrate a select gate removing process according to an embodiment of the present disclosure.

FIGS. 10 and 11 illustrate an example of a logic gate hard mask removing process in a second region according to an embodiment of the present disclosure.

FIGS. 12 and 13 illustrate an example of forming a logic gate according to an embodiment of the present disclosure.

FIGS. 14, 15, 16, 17, 18 and 19 illustrate an example of a control gate hard mask removing process in a first region by implementing an organic bottom anti-reflective coating layer according to an embodiment of the present disclosure.

FIG. 20 illustrates an example of forming a silicide layer and a metal interconnection process according to an embodiment of the present disclosure.

Throughout the drawings and the detailed description, unless otherwise described or provided, the same drawing reference numerals will be understood to refer to the same elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when a component is described as being “connected to,” or “coupled to” another component, it may be directly “connected to,” or “coupled to” the other component, or there may be one or more other components intervening therebetween. In contrast, when an element is described as being “directly connected to,” or “directly coupled to” another element, there can be no other elements intervening therebetween. Likewise, similar expressions, for example, “between” and “immediately between,” and “adjacent to” and “immediately adjacent to,” are also to be construed in the same way. As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

As used herein, the singular forms are intended to include the plural forms as well, unless the context clearly indicates otherwise. The terminology used herein is for describing various examples only and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application, and are not to be interpreted in an idealized or overly formal sense unless expressly so defined herein. The use of the term “may” herein with respect to an example or embodiment (e.g., as to what an example or embodiment may include or implement) means that at least one example or embodiment exists where such a feature is included or implemented, while all examples are not limited thereto.

Also, in the description of example embodiments, detailed description of structures or functions that are thereby known after an understanding of the disclosure of the present application will be omitted when it is deemed that such description will cause ambiguous interpretation of the example embodiments.

A term “part” or “module” used in the embodiments may mean software components or hardware components such as a field programmable gate array (FPGA), an application specific integrated circuit (ASIC). The “part” or “module” performs certain functions. However, the “part” or “module” is not meant to be limited to software or hardware. The “part” or “module” may be configured to be placed in an addressable storage medium or to restore one or more processors. Thus, for one example, the “part” or “module” may include components such as software components, object-oriented software components, class components, and task components, and may include processes, functions, attributes, procedures, subroutines, segments of a program code, drivers, firmware, microcode, circuits, data, databases, data structures, tables, arrays, and variables. Components and functions provided in the “part” or “module” may be combined with a smaller number of components and “parts” or “modules” or may be further divided into additional components and “parts” or “modules”.

Methods or algorithm steps (or operations) described relative to some embodiments of the disclosure may be directly implemented by hardware and software modules that are executed by a processor or may be directly implemented by a combination thereof. The software module may be resident on a RAM, a flash memory, a ROM, an EPROM, an EEPROM, a resistor, a hard disk, a removable disk, a CD-ROM, or any other type of record medium known to those skilled in the art. An exemplary record medium is coupled to a processor and the processor can read information from the record medium and can record the information in a storage medium. In another way, the record medium may be integrally formed with the processor. The processor and the record medium may be resident within an application specific integrated circuit (ASIC). The ASIC may be resident within a user's terminal.

Various embodiments of the present disclosure relate to a semiconductor device manufacturing method and a method for removing a hard mask used to form a pattern of a stacked gate in a method for manufacturing a non-volatile memory device as well as a logic device.

Hereinafter, examples will be described in detail with reference to the accompanying drawings, and like reference numerals in the drawings refer to like elements throughout.

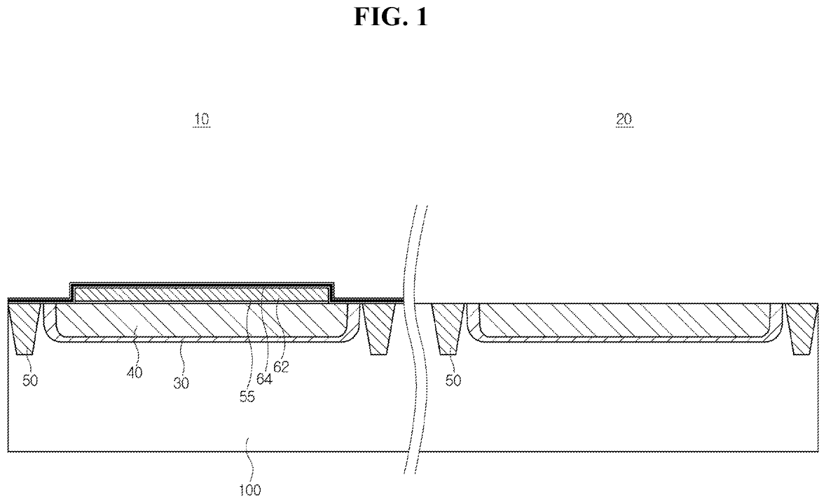

FIGS. 1, 2, 3 and 4 illustrate an example of forming a gate stack and a stacked structure according to an embodiment of the present disclosure.

Referring to FIG. 1, a first region 10 and a second region 20 are provided on a semiconductor substrate 100. A non-volatile memory device may be formed on the first region 10. The first region 10 can also be called a kind of cell area. The first region 10 and the second region 20 of the substrate 100 are prepared for semiconductor manufacture. The preparation may include cleaning the first region 10 and the second region 20 of chemical impurities and particles, heating for the desorption of water (removing moisture), treatment with an adhesion promoter, etc. (e.g., preparing the substrate for resist coating).

The second region 20 may be regarded as a region in which a logic device, an analog device, a digital device, or a memory device is formed. The second region may also be referred to as a logic region. Therefore, a non-volatile memory device, the logic device, the analog device, the digital device, or the memory device may be simultaneously formed on one substrate 100.

A deep well region 30 of a first conductive type may be formed in the first region 10 and the second region 20, respectively. In addition, a well region 40 of a second conductive type opposite to the first conductive type may be formed in the deep well regions 30, respectively. A shallow trench isolation (STI) structure 50 may be formed around the first region 10 and the second region 20.

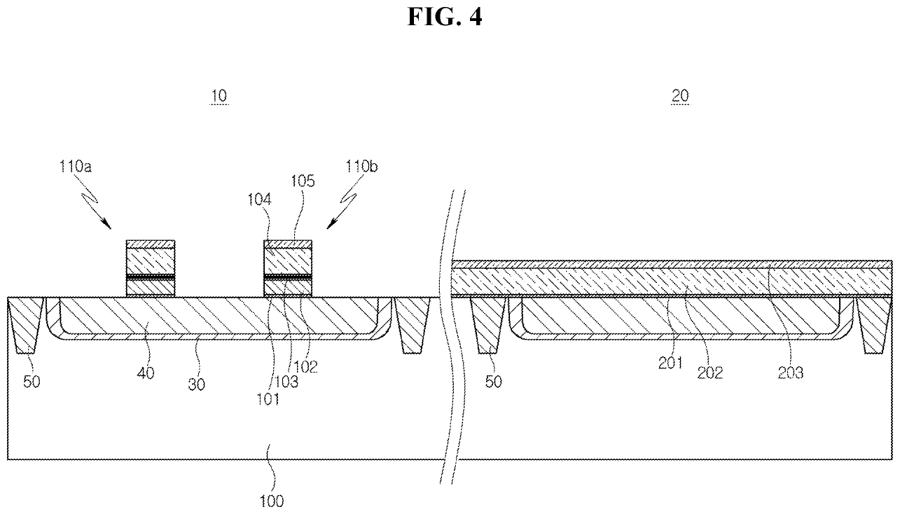

A tunneling gate insulating layer 55, a floating gate polysilicon layer (FG Poly-Si) 62, may be formed on the well region 40 in the first region 10. To form the FG Poly-Si 62, a conductive Poly-Si layer may be deposited on the semiconductor substrate 100. A patterning process may be performed on the conductive Poly-Si layer to form the FG Poly-Si 62 in the first region 10. The conductive Poly-Si layer in the second region 20 may be selectively removed by the patterning process. The FG Poly-Si 62 is to be a floating gate (FG) 102 (See FIG. 4).

The inter-poly dielectric layer 64 may be formed on the FG Poly-Si 62 in the first region 10. The inter-poly dielectric layer 64 may comprise SiO₂, SiN, SiO₂/SiN, or a high-k. The high-k may include Al₂O₃, HfO₂, Ta₂O₅, etc. To form the inter-poly dielectric layer 64, a dielectric layer may be deposited on the FG Poly-Si 62. Thereafter, a patterning process may be performed on the dielectric layer to form the inter-poly dielectric layer 64 in the first region 10. The dielectric layer in the second region may be selectively removed by the patterning process. The dielectric layer in the first region 20 becomes the inter-poly dielectric layer 64.

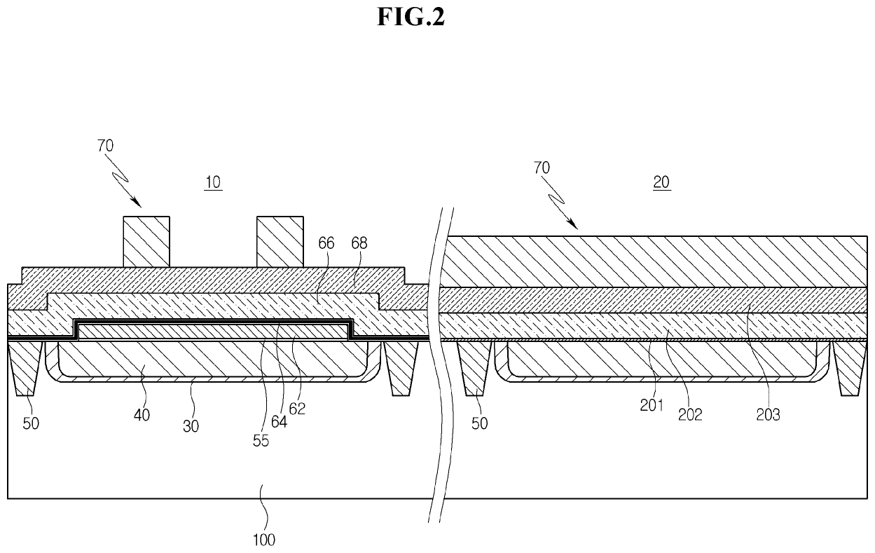

Referring to FIG. 2, a stacked structure may be formed in the second region. The stacked structure may comprise a logic gate insulating layer 201, a logic gate Poly-Si layer 202 and a logic gate hard mask layer 203.

At first, a logic gate insulating layer (LGox) 201 may be formed on the well region 40 in the second region 20. The LGox 201 may be formed by a thermal oxidation process at a high temperature. The LGox 201 may comprise SiO₂, SiON, or a high-k material. The high-k material may include HfO₂, Al₂O₃, Ta₂O₅, ZrO₂, etc. The LGox 201 may be formed with a separation step from the tunneling gate insulating layer 55.

Also, in order to minimize the manufacturing process cost, a control gate Poly-Si layer (CG Poly-Si) 66 and a logic gate Poly-Si layer (LG Poly-Si) 202 may be simultaneously deposited on the first region 10 and the second region 20, respectively. So the CG Poly-Si 66 and the LG Poly-Si 202 are formed at a same step and are made of a same material with each other. So the CG Poly-Si 66 and the LG Poly-Si 202 is a continuous single layer.

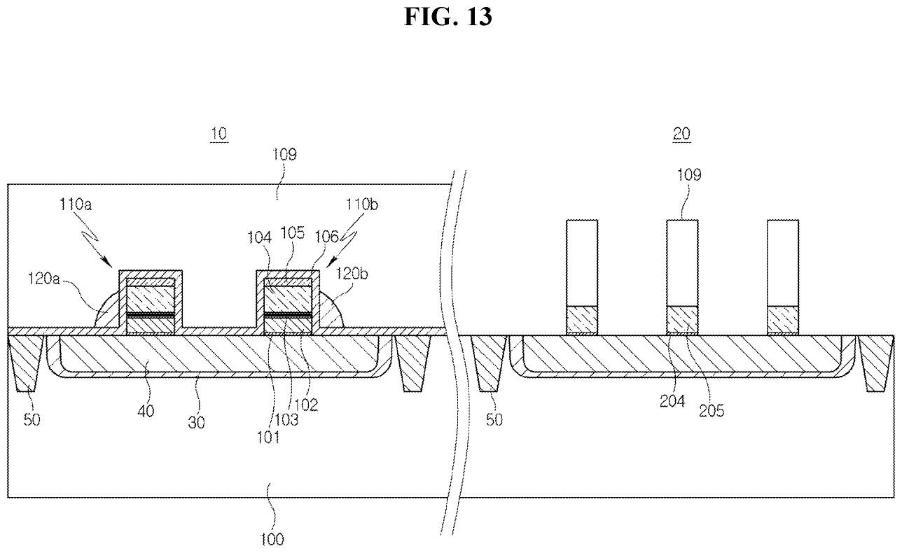

In the first region 10, the CG Poly-Si 66 is to be a control gate (CG) 104 (see FIG. 4). In the second region 20, the LG Poly-Si 202 is to be a logic gate (LG) 205 (see FIG. 13).

A control gate hard mask layer (CG HM) 68 and logic gate hard mask layer (LG HM) 203 may be simultaneously deposited on the CG Poly-Si 66 and a LG Poly-Si 202. So the CG HM 68 and the LG HM 203 are formed at a same step and are made of a same material with each other. So the CG HM 68 and the LG HM 203 is a continuous single layer.

The CG HM 68 and LG HM 203 may be deposited as a mask material for forming gate stacks 110a and 110b later. The CG HM 68 and LG HM 203 belong to an insulating layer and it may comprise SiO₂, SiN, SION, SiO₂/SiN, or the like.

A photomask pattern 70 may be formed to expose the CG HM 68 in the first region and to cover the LG HM 203 in the second region.

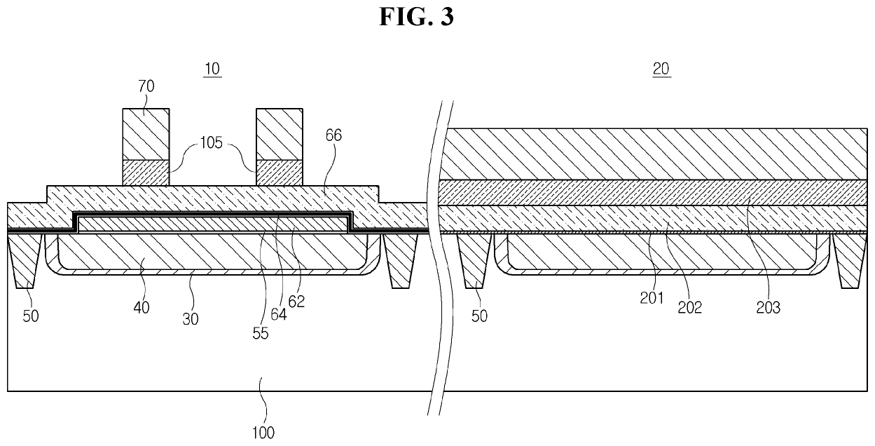

Referring to FIG. 3, a patterning process may be performed on the CG HM 68 to form a control gate hard mask (CG HM) 105 by implementing the photomask pattern 70. As-grown CG HM 68 in the first region 10 may be converted to a patterned CG HM 105 through the patterning process. A portion of the CG Poly-Si 66 may be partially etched in the first region 10 while the CG HM 105 is formed.

Referring to FIG. 4, a gate etching process may be performed on the exposed CG Poly-Si 66 to form gate stacks 110a and 110b by implementing the CG HM 105 and the photomask pattern (See FIG. 3) in the first region 10. Hereinafter, for convenience of description, the gate stacks 110a and 110b are referred to as a first gate stack 110a and a second gate stack 110b.

Subsequently, the inter-poly dielectric layer 64 and the FG Poly-Si 62 may be further etched during the gate etching process to form the first gate stack 110a and the second gate stack 110b in the first region. The LG Poly-Si 202 in the second region 20 may be protected by the LG HM 203 from the gate etching process.

During the gate etching process, the photomask pattern 70 may be consumed and its thickness may decrease, and may finally disappear. During the gate etching process, as-grown CG HM 68 and LG HM 203 may be shrunk in thickness to define the gate stacks 110a and 110b. As-grown CG HM 68 becomes a CG HM 105 after the gate etching process.

The first gate stack 110a and the second gate stack 110b may be formed symmetrically. A drain region or a source region (not shown) may be subsequently formed around the first gate stack 110a and the second gate stack 110b. The source region or the drain region (not shown) may be formed on the left side of the first gate stack 110a and on the right side of the second gate stack 110b.

The first gate stack 110a and the second gate stack 110b may include a tunneling gate insulating pattern 101, the FG 62, an inter-poly dielectric pattern 103, and the CG 104 sequentially stacked on the substrate 100. Here, the CG 104 may have a thickness greater than a thickness of the FG 62. The tunneling gate insulating pattern 101 may be a thin oxide layer and may affect the movement of electrons between the FG 62 and the substrate 100.

The FG 62 may be disposed on the tunneling gate insulating pattern 101. The FG 62 may comprise a Poly-Si or a metal layer. Electrons may be transferred from the FG 62 to the substrate 100 in accordance with a program voltage applied on the CG 104. Reversely, the electrons may be transferred from the substrate 100 to the FG 62 in accordance with an erase voltage applied on the CG 104.

The inter-poly dielectric pattern 103 may include a stacked layer comprising a silicon oxide layer (O), a silicon nitride layer (N), and a silicon oxide layer (O), named as ONO. The inter-poly dielectric pattern 103 may affect number of the transferred electrons between the FG 62 and the substrate 100.

The CG 104 may be disposed on the inter-poly dielectric pattern 103. The CG 104 may also comprise a Poly-Si or a metal layer. A program voltage or an erase voltage or a read voltage may be applied to the CG 104.

The CG HM 105 is an insulating layer and may comprise SiO₂, SiN, SiON, SiO₂/SiN, SiO₂/SiON or the like. As will be described later, a method for removing the CG HM 105 may be different depending on the material of the CG HM 105.

The LGox 201, the LG Poly-Si 202, and the LG HM 203 may be still remained in the second region 20. The LG HM 203 in the second region may be regarded as a protective layer for the LG Poly-Si 202. The LGox 201 in the second region may be disposed on the surface of the substrate 100 and may electrically insulate the LG Poly-Si 202 from the substrate 100. The LGox 201 may comprise SiO₂, SiN, SiON, or a high-k layer. The LG HM 203 may comprise the same material as the CG HM 105 in the first region.

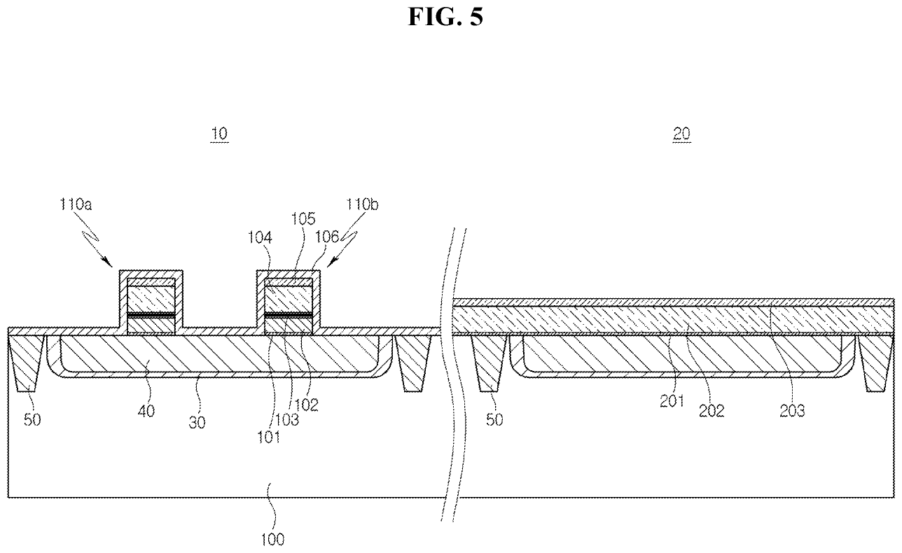

FIGS. 5, 6 and 7 illustrate an example of forming a select gate according to an embodiment of the present disclosure.

Referring to FIG. 5, a select gate insulating layer (SGox) 106 may be deposited on sidewalls of the gate stacks 110a and 110b in the first region 10. The SGox 106 may be also deposited on the top surface of the substrate 100 and on the first gate stack 110a, the second gate stack 110b, and the CG HM 105 and LG HM 203. Although not shown, the SGox 106 present in the second region 20 may be removed through a patterning process. Therefore, the SGox 106 can be formed only in the first region 10.

Here, the SGox 106 may comprise a single layer or multiple layers on the top surfaces of the substrate 100 and the CG HM 105 and LG HM 203. The SGox 106 may include at least any one of SiO₂, SiN, and SiON, and combination thereof. If the SGox 106 and the CG HM 105 and LG HM 203 are made of the same material (e.g., oxide layer), they may be indistinguishable from each other.

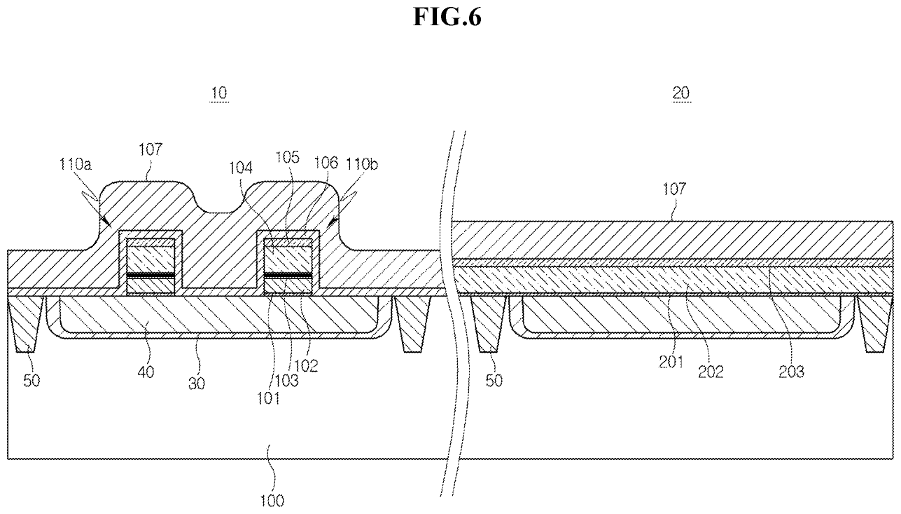

Referring to FIG. 6, a third conductive layer 107 may be formed on the top surface of the SGox 106 in the first region 10. Here, the third conductive layer 107 may comprise a Poly-Si or a metal layer. For example, highly doped Poly-Si layer may be implemented as the third conductive layer 107 to lower its resistance. The third conductive layer 107 may be deposited on both the first region 10 and the second region 20. The third conductive layer 107 may be conformally formed by a low-pressure chemical vapor deposition (LPCVD) method to have a uniform thickness.

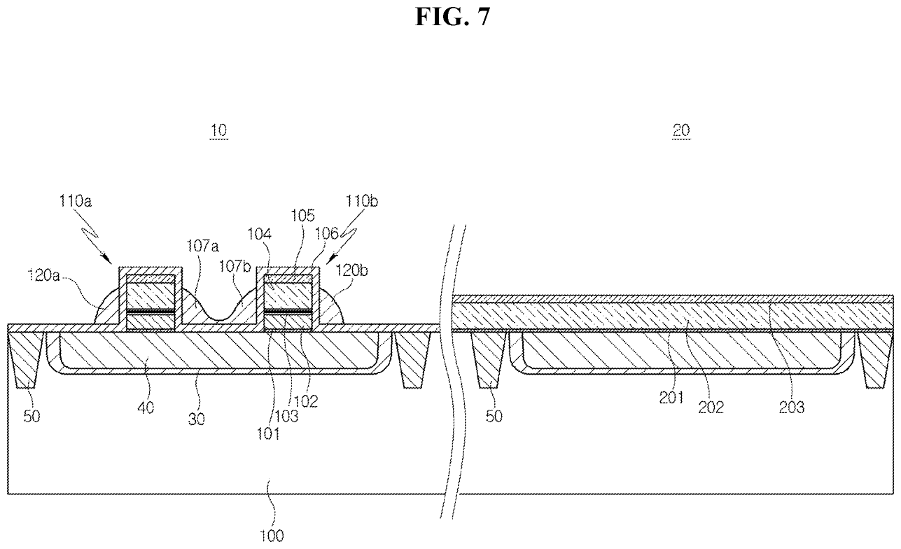

Referring to FIG. 7, a blanket or etch-back etching process may be performed on the third conductive layer 107 to form spacer-shaped select gates 120a, 107a, 107b, and 120b disposed on sides of the first and second gate stacks 110a and 110b in the first region 10. For example, the first select gate (SG) 120a may be formed on one side of the first gate stack 110a. In addition, the second SG 107a may be formed on an opposite side of the first gate stack 110a. Similarly, the third SG 107b may be formed on one side of the second gate stack 110b. Also, a fourth SG 120b may be formed on opposite side of the second gate stack 110b. Consequently, a first select gate 120a and a second select gate 120b are disposed on one sidewall of the gate stack 110a and 110b, respectively, as a spacer shape in the first region 10.

All of the third conductive layers 107 deposited on the LG Poly-Si 202 and the LG HM 203 in the second region 20 can be removed. However, the LG Poly-Si 202 and the LG HM 203 in the second region 20 still remain for formation of a logic gate.

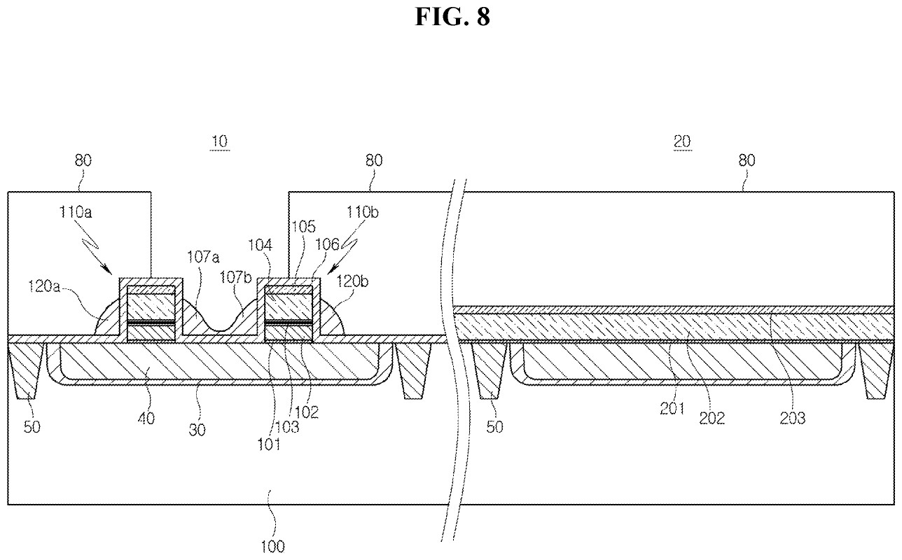

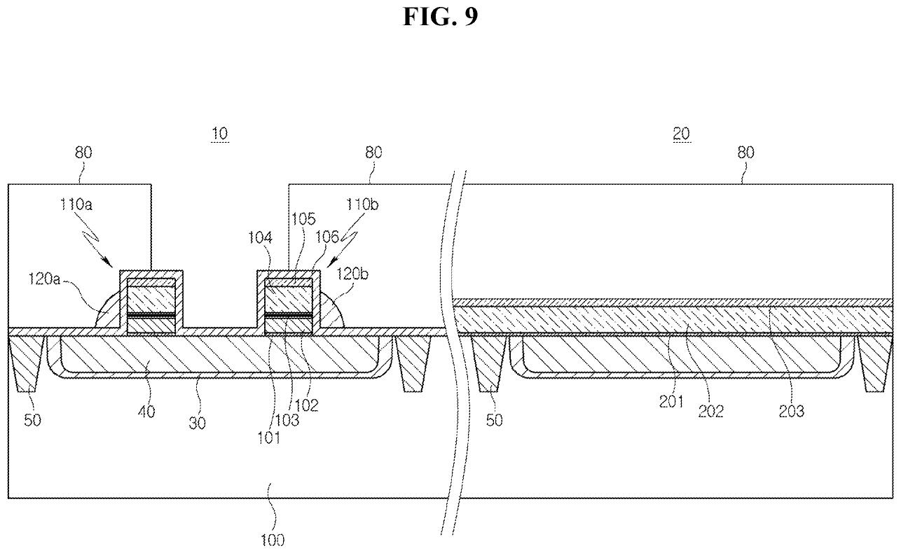

FIGS. 8 and 9 illustrate an example of a select gate removing process according to an embodiment of the present disclosure.

Referring to FIG. 8, a select gate removing photomask pattern 80 may be formed in a region other than between the first gate stack 110a and the second gate stack 110b. The select gate removing photomask pattern 80 may cover the first SG 120a, the second SG 120b and the second region 20, but it may open the second and third select gates 107a and 107b.

Referring to FIG. 9, a select gate removing process is performed to remove the second and third select gates 107a and 107b disposed between the first gate stack 110a and the second gate stack 110b by implementing the photomask pattern 80 as an etching mask.

After the select gate removing process, the select gate removing photomask pattern 80 may be removed by a plasma ashing process using oxygen plasma. The plasma ashing process using oxygen plasma may be a stripping process. The plasma ashing process can be performed under conditions of a gas pressure of 300 mTorr to 760 mTorr, a power of 1000 W to 1400 W, and an oxygen flow rate of 1000 SCCM to 1500 SCCM.

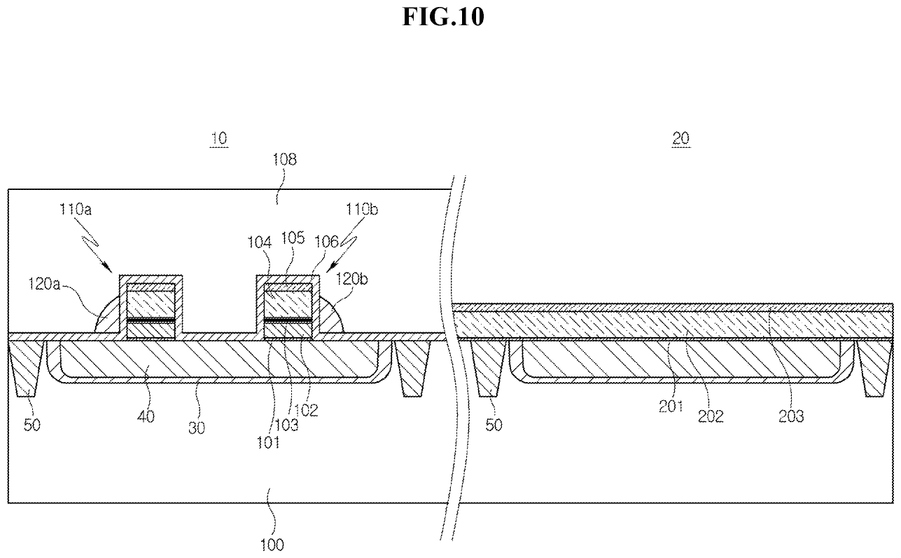

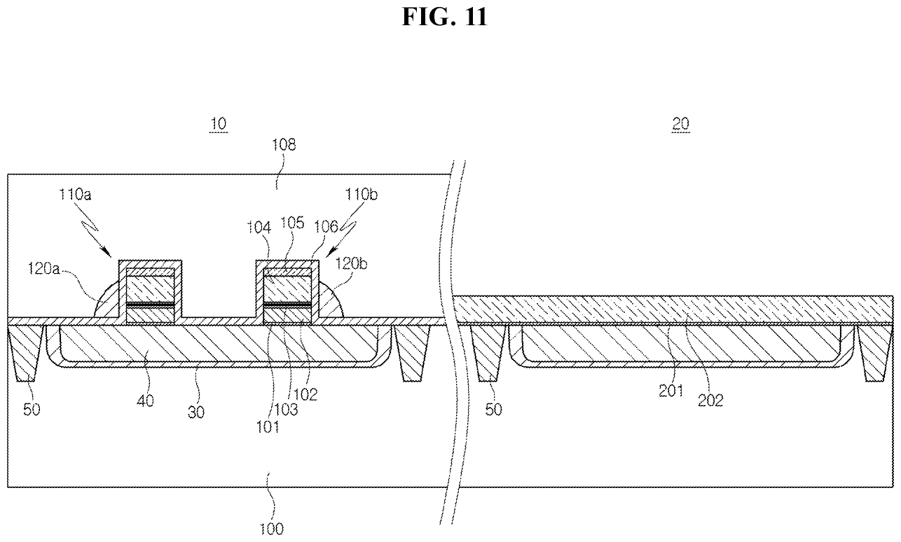

FIGS. 10 and 11 illustrate an example of a logic gate hard mask removing process in the second region according to an embodiment of the present disclosure.

Referring to FIG. 10, a photomask pattern 108 is formed to cover the first region 10, and to open the second region 20.

Referring to FIG. 11, a dry or a wet etching process is performed to remove the LG HM 203 stacked on the LG Poly-Si 202 in the second region 20 by implementing the photomask pattern 108 as an etching mask. After the dry or wet etching process, the photomask pattern 108 may be removed by the oxygen plasma ashing process. The plasma ashing process can be performed under conditions of a gas pressure of 300 mTorr to 760 mTorr, a power of 1000 W to 1400 W, and an oxygen flow rate of 1000 SCCM to 1500 SCCM.

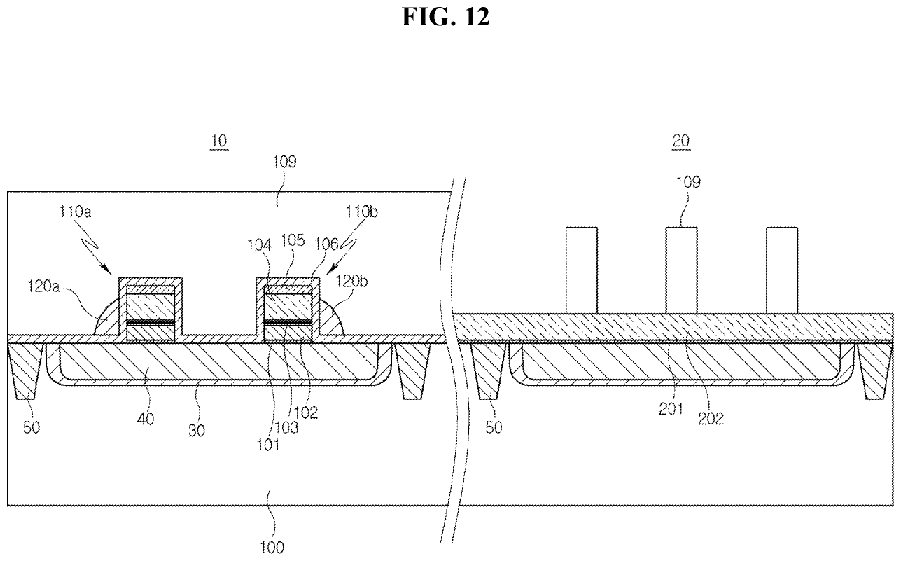

FIGS. 12 and 13 illustrate an example of forming a logic gate according to an embodiment of the present disclosure.

Referring to FIG. 12, a logic gate photomask pattern 109 may be formed on the first region 10 and the second region 20 to form a logic gate.

Referring to FIG. 13, a logic gate patterning process is performed on the LG Poly-Si 202 to form a logic gate (LG) 205 by implementing the logic gate photomask pattern 109 as an etching mask. The LGox 201 may be also patterned to form a logic gate insulating layer (LGox) 204. After the logic gate patterning process, the logic gate photomask pattern 109 may be removed by the oxygen plasma ashing process. The plasma ashing process can be performed under conditions of a pressure of 300 mTorr to 760 mTorr, a power of 1000 W to 1400 W, and an oxygen flow rate of 1000 SCCM to 1500 SCCM.

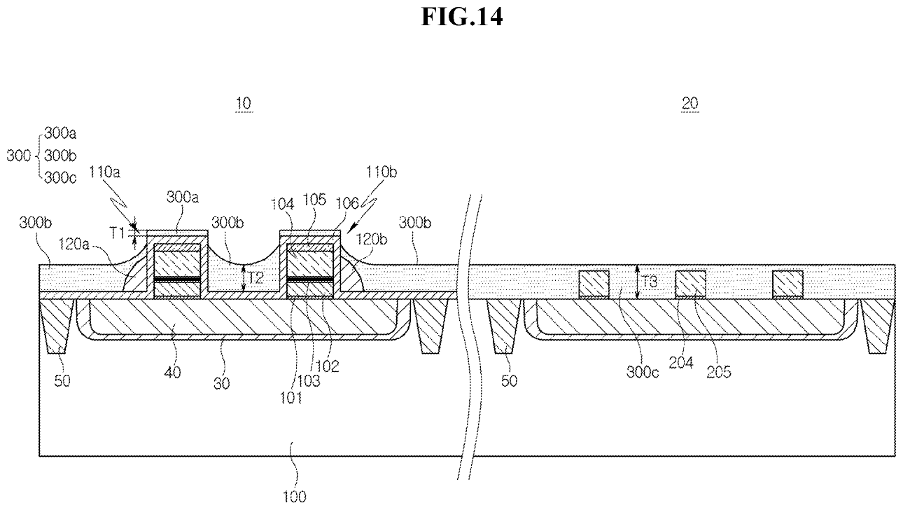

FIGS. 14, 15, 16, 17, 18 and 19 illustrate an example of a control gate hard mask removing process in a first region by implementing an organic bottom anti-reflective coating layer according to an embodiment of the present disclosure, i.e., a removing process on the select gate insulating layer and the control gate hard mask to expose a top surface of the control gate according to an embodiment of the present disclosure.

Referring to FIG. 14, the removing process is performed by implementing an organic bottom anti-reflective coating (BARC) layer 300. The BARC layer 300 may be coated over an entire region of the semiconductor substrate 100 by a spin coating process to form a spin-coated BARC layer 300.

In the embodiment of the present disclosure, a BARC layer 300 may comprise a material corresponding to DUV44, DUV30J, and DUV32 series. The DUV44, DUV30J, and DUV32 series are specialized in 248 nm lithography. The BARC layer 300 may be used to reduce the reflection of light during an exposure process. Therefore, the BARC layer 300 is formed in advance before a photomask pattern 206 is formed. The BARC layer 300 may also be referred to as a sacrificial layer because the BARC layer is finally removed.

After the spin coating process, a curing process may be performed at a temperature in a range from 100 to 250° C. for crosslinking, profiling or flattening of the spin-coated BARC layer 300. A solvent may escape through the curing process. Therefore, the curing process is also referred to as a bake process. The spin-coated BARC layer 300 becomes a solid BARC layer 300 after the curing process. The solid BARC layer 300 may be disposed on top or side surfaces of or around the gate stacks 110a and 110b, the select gates 120a and 120b, and the LG 205 having different heights, as well as on the SGox 106 and on the substrate 100.

The solid BARC layer 300 may comprise a first portion 300a, a second portion 300b, and a third portion 300c. The first, second and third portions 300a, 300b and 300c may have various thicknesses in locations due to the spin coating process. A geometric effect may induce the various thicknesses of the BARC layer 300.

The first portion 300a of the solid BARC layer 300 having a first thickness T1 may be disposed on the gate stacks 110a and 110b, or on the top surface of the CG HM 105.

The second portion 300b of the solid BARC layer 300 having a second thickness T2 on average may be disposed in a space between the gate stacks 110a and 110b. In addition, the second portion 300b may be disposed on the select gates 120a and 120b. The second portion 300b disposed on the select gates 120a and 120b has a thickness less than a thickness of the second portion 300b disposed in a space between the gate stacks 110a and 110b.

The third portion 300c of the solid BARC layer 300 having a third thickness T3 is disposed around the LG 205 in the second region 20.

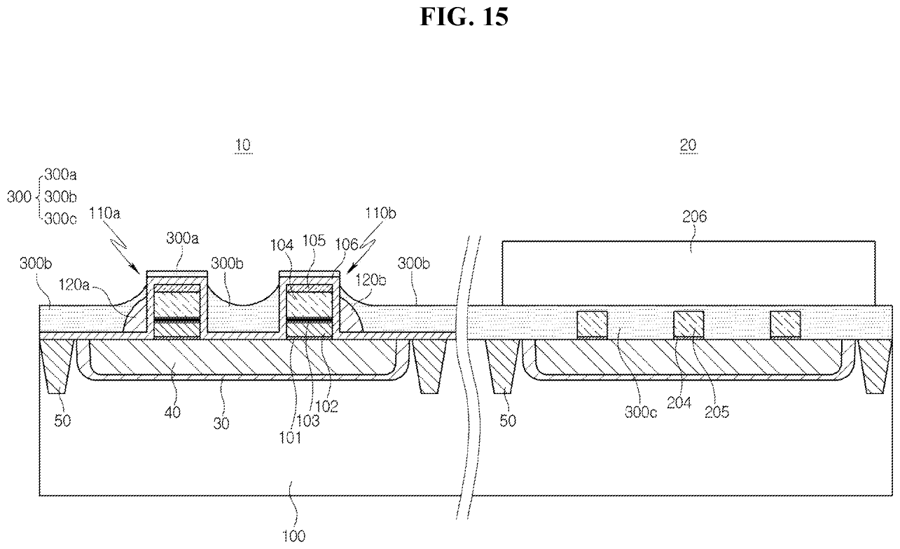

Referring to FIG. 15, a photomask pattern 206 may be formed to expose the BARC layer 300 in the first region 10 and to cover the BARC layer 300 in the second region 20. The photomask pattern 206 may protect the BARC layer 300 disposed in the second region 20 during a subsequent BARC etching process.

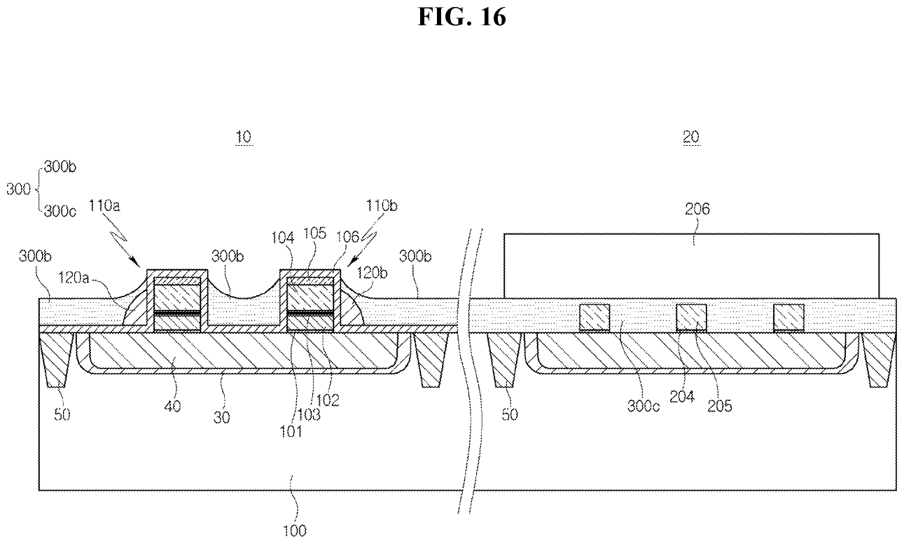

Referring to FIG. 16, a BARC etch-back process may be performed on the BARC layer 300. Here, the BARC etch-back process may be performed in a plasma etching chamber. The first portion 300a disposed on the CG HM 105 in the first region 10 may be removed by the BARC etch-back process.

Here, the BARC etch-back process may be performed by a descum process. The descum process can be performed under conditions of a gas chamber pressure of 400 mTorr to 760 mTorr, a plasma power of 300 W to 760 W, and an oxygen flow rate of 100 SCCM to 400 SCCM. Compared to a normal ashing process, the descum process can be carried out under conditions of much less power and much less oxygen flow rate to remove only the first portion 300a. The descum process is performed with oxygen flow rate lower than an oxygen flow rate of the plasma ashing process. The descum process is also performed with a plasma power lower than a plasma power of the plasma ashing process.

If process conditions to the power and oxygen flow rate are employed as the normal ashing process, not only the first portion 300a but also the second portion 300b may be totally removed. Therefore, the BARC etch-back process is performed such that only the first portion 300a can be removed if possible by controlling appropriate amounts of oxygen flow rate, pressure, and power. The second portion 300b may be slightly removed by the BARC etch-back process.

The BARC etch-back process may be also performed by a plasma etching process, rather than the descum process described above. The plasma etching process may be performed under O₂/CHF₃/Ar, C₂F₆, Cl₂, N₂/O₂, O₂/HBr/HCl plasma gases to remove the first portion 300a.

The BARC etch-back process may be also performed by a chemical etching process, rather than the descum process described above. The chemical etching process may be performed under Piranha solution to remove the first portion 300a. The Piranha solution may comprise sulfuric acid (H₂SO₄) and hydrogen peroxide (H₂O₂).

Referring to FIG. 16, the BARC etch-back process may be performed until the SGox 106 or the CG HM 105 may be exposed. After the BARC etch-back process, a hard mask removal process may be followed to remove the CG HM 105 in the first region 10. The hard mask removal process may be performed by a dry etching process or a wet etching process.

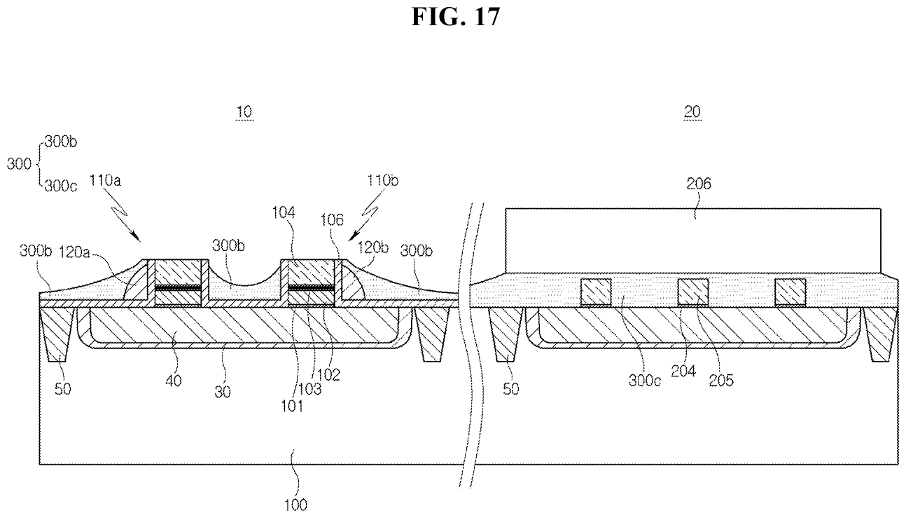

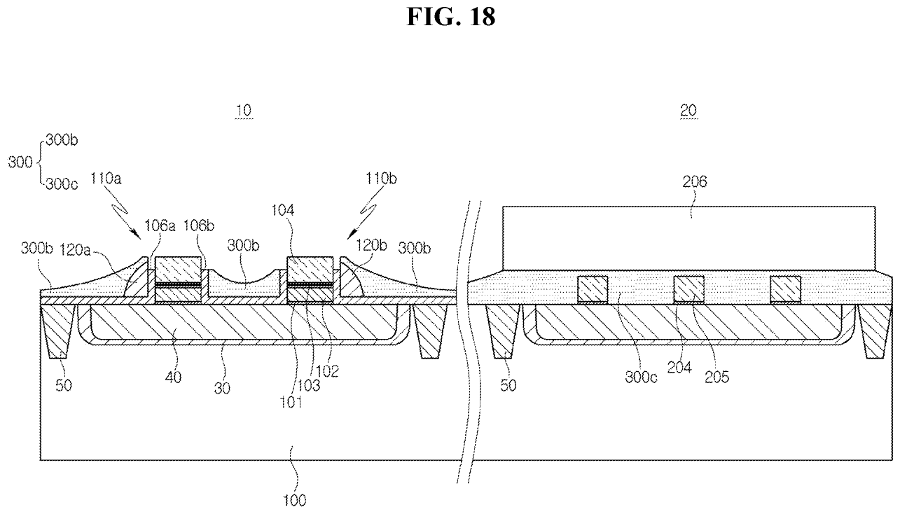

FIGS. 17 and 18 illustrate a dry etching process or a wet etching process for removal of the select gate insulating layer and the hard mask.

Referring to FIG. 17, a dry etching process may be performed to remove the SGox 106 and the CG HM 105, wherein the dry etching process uses the same plasma chamber as the BARC etch-back process. There is no change in plasma chamber between the BARC etch-back process and the dry etching process, which results in reducing a fabrication cost. The dry etching process may be performed with a reactive ion etching (RIE) process. RIE process may be performed under plasma gases, such as CHF₃, CF₄, Ar, or SF₆. The RIE process belongs to an anisotropic etching process.

The dry etching process may be performed to completely remove the CG HM 105 to expose the CG 104. If the CG HM 105 remains on the CG 104, a silicide layer 303 may not be formed on the CG 104.

During the dry etching process, the second portion 300b may be partially etched in the first region 10.

Referring to FIG. 18, the SGox 106 and the CG HM 105 may be removed by the wet etching process. The SGox 106 and the CG HM 105 may be easily removed with a chemical etching solution such as HF or buffered oxide etchant (BOE). The wet etching process may be also called as an isotropic etching process. There is an advantage that the wet etching process may give no plasma damage on the CG 104.

The select gate insulating layers 106a and 106b disposed on sidewalls of the gate stacks 110a and 110b may be partially etched during the wet etching process, which results in decrease in thickness. Therefore, each top surface of the select gate insulating layers 106a and 106b may be lower than a top surface of the CG 104.

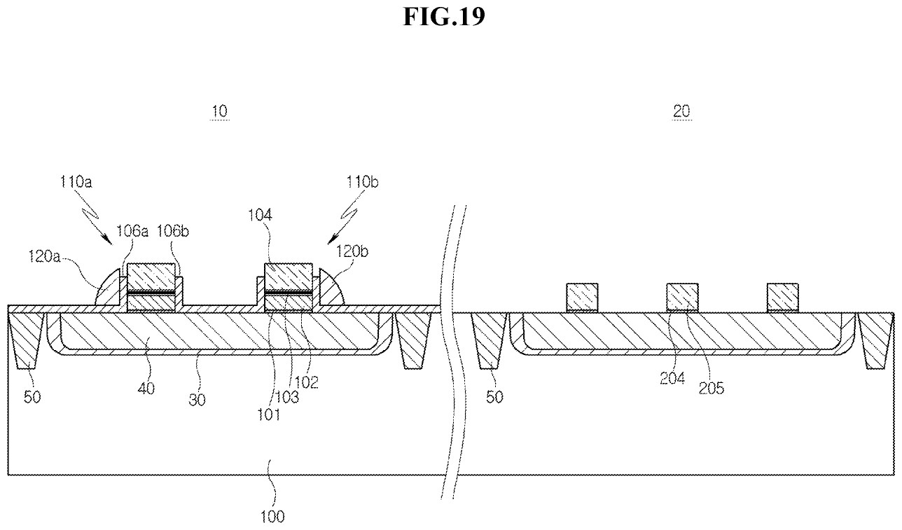

FIG. 19 illustrates a BARC removal process in the first and second regions.

Referring to FIG. 19, a plasma ashing process may be performed by implementing oxygen plasma gas to remove the photomask pattern 206 in the second region 20. The plasma ashing process may also remove the remaining second and third portions 300b and 300c disposed in the first region 10 and the second region 20, respectively. The plasma ashing process can be performed under conditions of a pressure of 300 m Torr to 760 m Torr, a power of 1000 W to 1400 W, and an oxygen flow rate of 1000 SCCM to 1500 SCCM. After the plasma ashing process, a cleaning process may be subsequently performed to remove Polymer residue.

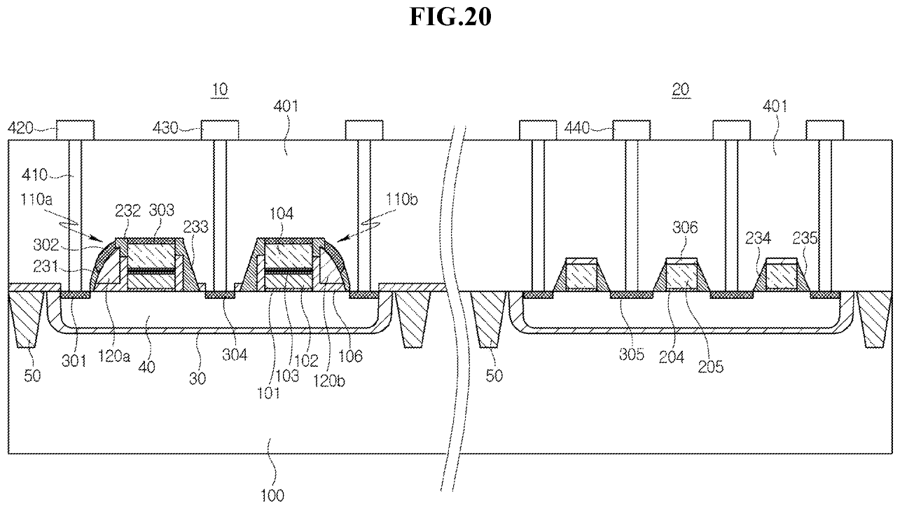

FIG. 20 illustrates an example of forming a silicide layer process and a metal interconnection process according to an embodiment of the present disclosure.

Referring to FIG. 20, selection gate (SG) spacers 231 and 232, lightly-doped drain (LDD) spacer 233, logic gate (LG) spacers 234, and 235 may be simultaneously formed on the substrate 100. The selection gate (SG) spacers 231 and 232 are formed on sidewalls of the selection gate 120a or 120b. The LDD spacer 233 is disposed on sidewalls of the gate stack 110a or 110b. The LG spacers 234 and 235 are disposed on sidewalls of the LG 205.

Silicide layers 301, 302, 303, 304, 305, and 306 may be simultaneously formed on the substrate 100. Specifically, the silicide layers 301 and 304 are formed on a source region or a drain region in the well region 40. First silicide layers 302 are formed on the select gates 120a and 120b. Second silicide layers 303 are formed on the CG 104. Third silicide layers 305 are formed on the substrate 100 in the second region 20. Fourth silicide layers 306 are formed on the LG 205.

Here, first silicide layers 302 formed on the select gates 120a and 120b may be disposed between the first and second SG spacers 231 and 232. The second SG spacer 232 may be required to separate the first silicide layers 302 from the second silicide layers 303 disposed on the CG 104.

Also, an etch stop layer (not shown) may be deposited on the various spacers 231, 232, 233, 234, and 235 and the silicide layers 301, 302, 303, 304, 305, and 306. An interlayer insulating layer (ILD) 401 is subsequently deposited on the entire surface of the substrate 100, and then a plurality of contact holes (not shown) is formed in the ILD 401. A plurality of contact plugs 410 may be formed in the contact holes. Here, the silicide layers 301 to 306 may be connected to the plurality of contact plugs 410, respectively. In addition, metal wires 420, 430 and 440 connected to the plurality of contact plugs 410 respectively may be formed.

Although the disclosure has been described with reference to the embodiment shown in the drawings, this is an example and it will be understood by those skilled in the art that various modifications and equivalent thereto may be made. Therefore, the true technical scope of the disclosure should be determined by the spirit of the appended claims.

According to the embodiment of the present disclosure, a manufacturing method for the non-volatile memory device are provided by implementing BARC materials.

Accordingly, a semiconductor device manufacturing method is provided which not only removes the oxide layer on the stacked gate by implementing bottom anti-reflective coating (BARC) but also prevents the tunnel oxide layer 55 below the floating gate Poly-Si layer 62 and the dielectric layer pattern (or structure) 103 between the floating gate Poly-Si layer 62 and the control gate 104 from being damaged.

Advantageous effects that can be obtained from the present disclosure are not limited to the above-mentioned effects. Further, other unmentioned effects can be clearly understood from the following descriptions by those skilled in the art to which the present disclosure belongs,

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A semiconductor device manufacturing method comprising: preparing a first region and a second region on a substrate;
forming a tunneling gate insulating layer and a floating gate Poly-Si layer in a first region and a second region of a substrate;
forming an inter-poly dielectric layer on the floating gate Poly-Si layer;
forming a control gate Poly-Si layer on the inter-poly dielectric layer;
forming a control gate hard mask layer on the control gate Poly-Si layer;
performing a patterning process on the control gate hard mask layer, the control gate Poly-Si layer, the inter-poly dielectric layer, the floating gate Poly-Si layer and the tunneling gate insulating layer to form a gate stack comprising a control gate hard mask, a control gate, an inter-poly dielectric pattern, a floating gate and a tunneling gate insulating pattern;
forming a select gate insulating layer on the gate stack;
forming a select gate disposed on the select gate insulating layer, wherein the select gate is disposed on one sidewall of the gate stack having a spacer shape;
performing a removing process on the select gate insulating layer and the control gate hard mask to expose a top surface of the control gate; and
forming a silicide layer on the control gate.

2. The semiconductor device manufacturing method of claim 1, wherein the performing of a removing process comprises:
coating an organic bottom anti-reflective coating (BARC) layer on the gate stack;
partially removing the BARC layer disposed on the gate stack, resulting in exposing the select gate insulating layer;
removing the select gate insulating layer and the control gate hard mask disposed on the control gate; and
removing the remaining BARC layer.

3. The semiconductor device manufacturing method of claim 2, wherein the partially removing of the BARC layer comprises a dry etch-back process.

4. The semiconductor device manufacturing method of claim 2, wherein the removing of the select gate insulating layer and the control gate hard mask disposed on the control gate comprises at least one of a dry etching process, a wet etching process, or a combination thereof.

5. The semiconductor device manufacturing method of claim 3, wherein the removing of the remaining BARC layer comprises a plasma ashing process.

6. The semiconductor device manufacturing method of claim 5,
wherein the dry etch-back process comprises a descum process, and
wherein a process condition in the descum process comprises an oxygen flow rate and a plasma power lower than those of the plasma ashing process.

7. The semiconductor device manufacturing method of claim 2, wherein the BARC comprises:
a first portion covered on the gate stack; and
a second portion covered on the select gate, the second portion having a thickness greater than a thickness of the first portion.

8. The semiconductor device manufacturing method of claim 1, further comprising:
forming a logic gate insulating layer in the second region of the substrate;
forming a logic gate Poly-Si layer on the logic gate insulating layer; and
forming a logic gate hard mask layer on the logic gate Poly-Si layer,
wherein the logic gate hard mask layer is simultaneously formed with the control gate hard mask layer.

9. The semiconductor device manufacturing method of claim 2, wherein the removing of the BARC layer is implemented while minimizing damage to the tunneling gate insulating layer below the floating gate Poly-Si layer and the inter-poly dielectric pattern between the floating gate Poly-Si layer and the control gate.

10. A semiconductor device manufacturing method comprising: preparing a first region and a second region on a substrate;
forming a gate stack in the first region, the gate stack comprising a control gate hard mask, a control gate, an inter-poly dielectric pattern, a floating gate, and a tunneling gate dielectric pattern;
forming a stacked structure in the second region, the stacked structure comprising a logic gate insulating layer, a logic gate Poly-Si layer, and a logic gate hard mask layer;
forming a select gate disposed on one sidewall of the gate stack as a spacer shape in the first region;
removing the logic gate hard mask layer disposed on the logic gate Poly-Si layer, and patterning the stacked structure to form a logic gate in the second region;
removing the control gate hard mask to expose the control gate; and
forming a silicide layer on the control gate in the first region.

11. The semiconductor device manufacturing method of claim 10, wherein the removing of the control gate hard mask comprises:
forming a coating layer to cover the gate stack and the stacked structure;
partially etching the coating layer to expose the control gate hard mask layer;
removing the control gate hard mask layer; and
removing the coating layer disposed on the gate stack and the stacked structure.

12. The semiconductor device manufacturing method of claim 11, wherein the coating layer comprises a bottom anti-reflective coating (BARC) layer.

13. The semiconductor device manufacturing method of claim 10, wherein the forming of the gate stack in the first region comprises:
forming a tunneling gate insulating layer and a floating gate Poly-Si layer in the first region;
forming an inter-poly dielectric layer on the floating gate Poly-Si layer;
forming a control gate Poly-Si layer on the inter-poly dielectric layer;
forming a control gate hard mask layer on the control gate Poly-Si layer; and
performing a patterning process on the control gate hard mask layer, the control gate Poly-Si layer, the inter-poly dielectric layer, the floating gate Poly-Si layer and the tunneling gate insulating layer to form a control gate hard mask, a control gate, an inter-poly dielectric pattern, a floating gate and a tunneling gate insulating pattern.

14. The semiconductor device manufacturing method of claim 11,
wherein the partially etching of the coating layer comprises a descum process using oxygen plasma.

15. The semiconductor device manufacturing method of claim 11, wherein the removing of the control gate hard mask layer comprises at least one of a dry etching process, a wet etching process or a combination thereof.

16. The semiconductor device manufacturing method of claim 14, wherein the removing of the coating layer disposed on the gate stack and the stacked structure comprises an ashing process using oxygen plasma, and
wherein the descum process operates at oxygen flow rates lower than a plasma ashing process.
